(19) United States
(12) Patent Application Publication
(10) Pub. No.: US 2022/0093838 A1
(43) Pub. Date: Mar. 24, 2022

(54) HEAT EXCHANGER

(71) Applicant: Mahle International GmbH, Stuttgart (DE)

(72) Inventor: Andreas Kemle, Tamm (DE)

(21) Appl. No.: 17/483,780

(22) Filed: Sep. 23, 2021

(30) Foreign Application Priority Data
Sep. 24, 2020 (DE) 102020212040.4

(51) Int. Cl. H01L 35/02; B60N 2/58; B60N 2/56; D03D 1/00; H01L 35/32

(52) U.S. Cl. CPC H01L 35/02; B60N 2/58; B60N 2/5678; D10B 2401/041; H01L 35/32; D10B 2401/18; D03D 1/0088

(57) ABSTRACT

A method for operating a heat exchanger comprising a top side, a bottom side, and a thermoelectric device including thermoelectrically active elements which are electrically energizable for generating a heat flow between the top side and the bottom side, the method may comprise electrically energizing the thermoelectric device with an electric alternating current.

### CROSS-REFERENCE TO RELATED APPLICATION

This application claims priority to German Application No. DE 10 2020 212 040.4 filed on Sep. 24, 2020, the contents of which are hereby incorporated by reference in its entirety.

### TECHNICAL FIELD

The invention relates to a method for operating a heat exchanger and to a heat exchanger which is designed for carrying out this method. Furthermore, the invention relates to a vehicle seat having such a heat exchanger.

### BACKGROUND

Usually, vehicle seats in modern motor vehicles are heated with the help of electric heating wires or electric heating mats, which have a suitable electrical impedance so that they convert electric power into heat, which is liberated on the vehicle seat. Likewise, such vehicle seats can be equipped with a so-called thermoelectric surface cooling system, which comprises thermoelectrically active elements. Through suitable electrical energization of the thermoelectrically active elements these assume the function of a heat exchanger which transports heat away from the vehicle seat to a fluid path that can be flowed through by a fluid. The fluid acting as coolant absorbs the heat transported away from the vehicle seat by means of the heat exchanger. In this way, the vehicle seat can be cooled.

Through reversed electric current it is conceivable to use the thermoelectric surface cooling system as additional heating device, which transports heat in the opposite direction, i.e. from the fluid path or from the fluid towards the vehicle seat.

However it proves disadvantageous in this that the extraction of heat from the fluid or fluid path accompanied by this an additional cooling of the same is brought about which in an extreme case can lead to an icing-up of the fluid mass flow and thus to a total failure of the entire surface cooling system.

A use of the said electrical heating wires or heating mats for heating the vehicle seat combined with a thermoelectric surface cooling system for cooling the vehicle seat can be technically realised only with major effort and thus expense. In addition, relatively much installation space is required for this purpose since two devices that generally operate independently of one another have to be installed.

### SUMMARY

It is therefore an object of the present invention to create an improved method for operating a heat exchanger which deals with the abovementioned problems or in the case of which the abovementioned disadvantages are at least partly, ideally even completely eliminated.

This object is solved through the subject of the independent patent claims. Preferred embodiments are subject of the dependent patent claims.

Accordingly, the basic idea of the invention is to electrically energize with an alternating current the thermoelectrically active elements of a heat exchanger whose top side can be thermally connected to the seating surface of a vehicle seat and the bottom side of which can be thermally connected to a fluid path that can be flowed through by a fluid so that the Joule heat generated by the thermoelectric elements and reaching the bottom side is transported by the thermoelectrically active elements functioning as thermoelectric heat pump from the bottom side—i.e. from the fluid path—to the top side—i.e. to the vehicle seat or its seating surface.

In this way, the top side can be heated through heat supply. Since the Joule heat “flowing” to the bottom side—i.e. to the heat sink—is transported to the top side by means of the thermoelectric heat pump it is not necessary to discharge the Joule heat incurred on the bottom side in another manner—for example via a suitable cooling medium—for example air—since this object is taken over by the thermoelectric heat pump. Thus, the Joule heat incurred is utilised on the one hand for heating the top side and on the other hand an undesirable cooling-down of the bottom side—under certain conditions accompanied by damage to or even destruction of the bottom side through condensed air—avoided. In the ideal case, the entire Joule heat reaching the bottom side is thus pumped “nett” from the thermoelectric heat pump to the top side.

According to the invention it is proposed in this regard to select the electric alternating current so that an average first period, in which the electric energization of the thermoelectrically active elements takes place in such a manner that the same discharge heat from the top side, is shorter than an average second period, in which the electric energization of the thermoelectrically active element takes place in such a manner that the same supply heat to the top side.

Alternatively or additionally it is proposed according to the invention that an average first current, in which the electric energization of the thermoelectrically active elements takes place in such a manner that heat is transported from the top side to the bottom side is smaller than an average second current, in which the electric energization of the thermoelectrically active elements takes place in such a manner that heat is transported from the bottom side to the top side.

Since thus more heat is pumped “nett” from the bottom side to the top side than vice versa, the aspired heating of the top side can be achieved with the simultaneous provision of electric heating output, whereas the temperature of the bottom side remains substantially constant. In this way it can be avoided that the temperature of the bottom side falls below a critical value that is not acceptable.

By means of the method introduced here an effective heating of the top side of the heat exchanger—and upon integration in a vehicle seat of the seating surface of the same—is possible without separate electrical heating wires or heating mats being required for this purpose. In particular, a thermoelectric heat pump can be used which is actually designed for cooling the seating surface of the vehicle seat in that the thermoelectric heat pump is utilised in the conventional manner to pump heat from the top side to the bottom side and there discharge the said heat from the vehicle seat by means of a suitable cooling medium—for example air.

The terms “top side” and “bottom side” in the context of the present invention are to be understood with a view to a preferred usage position of the heat exchanger relative to the direction of the gravitational force when the method according to the invention is carried out. This means that the top side of the heat exchanger when the method is carried out is typically arranged, with respect to the direction of the force of gravity, above the bottom side of the heat exchanger. This is the case for example when the heat exchanger is arranged and used in a vehicle seat of a motor vehicle. However, scenarios are also conceivable and expressly included in the scope of protection of the present invention, in which the top side with respect to the direction of the force of gravity is not arranged above but below the bottom side. This can be the case for example when the heat exchanger is arranged in a headlining of the motor vehicle so that the top side with respect to the direction of the force of gravity points downwards towards the vehicle interior.

The method according to the invention serves for operating a heat exchanger which comprises a top side and a bottom side and a thermoelectric device with thermoelectrically active elements. The thermoelectric device is designed so as to be electrically energizable for generating a heat flow between the top side and the bottom side. According to the method, the thermoelectric device is energized with an electric alternating current in such a manner that an average first period, in which the electric energization of the thermoelectrically active elements takes place in such a manner that heat is transported from the top side to the bottom side, is shorter than an average second period, in which the electric energization of the thermoelectrically active elements takes place in such a manner that heat is transported from the bottom side to the top side; alternatively or additionally, an average first current, in which the electric energization of the thermoelectrically active elements takes place in such a manner that heat is transported from the top side to the bottom side takes place with the method according to the invention in such a manner that heat is transported from the top side to the bottom side is selected lower than an average second current in which the electric energization of the thermoelectrically active elements takes place in such a manner that heat is transported from the bottom side to the top side.

For electrically energizing the thermoelectrically active elements with an electric alternating current a suitable electric alternating power source can be used.

According to a preferred embodiment, the electric energization of the thermoelectrically active elements also includes a zero value for the electric alternating current. This means that an interruption of the electric current takes the place of an electric current flow through the thermoelectrically active element.

According to an advantageous further development, the average first period and the average second period or the average first current and the average second current are fixed so that the heat quantity transmitted during a cycle of the alternating current from the bottom side to the top side corresponds to the heat quantity transported from the top side to the bottom side plus the heat quantity generated by the thermoelectric elements and transported to the bottom side. In this way, an undesirable cooling or temperature reduction on the bottom side of the heat exchanger can be largely or even completely avoided.

Particularly preferably, the average first period and the average second period or the average first current and the average second current are fixed so that a temperature of the top side of the heat exchanger converges towards a defined temperature limit value. Alternatively or additionally, the average first period and the average second period or the average first current and the average second current in this version are fixed so that a temperature of the bottom side remains substantially constant. In this way, an overheating of the top side or of a seating surface of a vehicle seat thermally connected to the top side is avoided.

Particularly preferably, an electric alternating current with a predetermined cycle ratio is generated so that the average second period amounts to at least 1.5 times, preferentially at least two times and maximally ten times, preferentially maximally five times the average first period. Experimental investigations have shown that with such a cycle ratio the desired convergence of the temperature of the top side of the heat exchanger to a predetermined convergence value and a maintaining of the temperature of the bottom side can be particularly effectively achieved.

Practically, the cycle ratio can be taken from a predetermined characteristic map. In particular, the current temperatures of the top side and bottom side as well as the magnitude of the electric current in each flow direction can go into this characteristic map as input quantities. In this way, the method according to the invention can be effectively adapted to a wide variety of external method parameters.

Practically, an alternating current frequency of the electric alternating current amounts to at least 1 Hz, preferentially at least 10 Hz. In this way, undesirable temperature fluctuations, in particular on the top side of the heat exchanger, are largely or even completely avoided.

The invention also relates to a heat exchanger for temperature controlling a vehicle seat. The heat exchanger according to the invention includes a thermoelectric device comprising multiple electrically energizable thermoelectrically active elements which are arranged spaced apart from one another between a top side and a bottom side of the heat exchanger. The heat exchanger according to the invention additionally includes a fluid path that is thermally connected to the bottom side for being flowed through by a fluid and a control/regulating device, which is designed for carrying out the method according to the invention. The advantages of the method according to the invention explained above thus apply also to the heat exchanger according to the invention.

Particularly preferably, the heat exchanger is designed so that it can be connected to an electric power source for generating the electric current in the thermoelectric device. Practically, this electric power source can be controlled by the control/regulating device so that in particular the generating of the electric alternating current required for carrying out the method according to the invention can take place.

According to an advantageous further development, a heat transferring structure for transferring heat between the fluid conducted through the fluid path and the thermoelectrically active elements is arranged between the thermoelectrically active elements and the fluid path. By means of this measure, the heat transfer between the fluid path and the thermoelectric elements and thus between the bottom side and the top side of the heat exchanger can be substantially improved.

Particularly preferably, the thermoelectric device can include multiple electrical conductor bridges for electrically interconnecting the thermoelectrically active elements. A thermoelectric device designed in such a manner can be technically realised particularly easily and therefore brings with it substantial cost advantages.

According to an advantageous further development, the electric conductor bridges include first conductor bridges facing the bottom side, which form the cold side of the thermoelectric device, and second conductor bridges facing the top side, which form the warm side of the thermoelectric device.

According to an advantageous further development, the thermoelectric device comprises a thermoelectric fabric or is formed as thermoelectric fabric. This further development is particularly suitable for integrating the heat exchanger in a vehicle seat for a motor vehicle. With this further development, thermoelectric fabric can preferably include a plurality of first threads, which alternately include p-doped and n-doped thread portions and electrically conductive first and second thread portions arranged in between, wherein the first thread portions of the fabric form the first conductor bridges of the heat exchanger and the second thread portions of the fabric the second conductor bridges of the heat exchanger. Furthermore, the fabric includes a plurality of second threads which are formed so as to be preferentially electrically insulating. Apart from this, the first threads form the warp threads and the second threads the weft threads of the fabric in this development or vice versa.

Further important features and advantages of the invention are obtained from the sub-claims, from the drawings and from the associated figure description by way of the drawings.

It is to be understood that the features mentioned above and still to be explained in the following cannot only be used in the respective combinations stated but also in other combinations or by themselves without leaving the scope of the present invention.

Preferred exemplary embodiments of the invention are shown in the drawings and are explained in more detail in the following description, wherein same reference numbers relate to same or similar or functionally same components.

### BRIEF DESCRIPTION OF THE DRAWINGS

It shows, in each case schematically:

FIG. 1 an example of a heat exchanger according to the invention with electrically energized thermoelectric elements of the heat exchanger in a first electric current direction,

FIG. 2 the heat exchanger of FIG. 1 with electrically energized thermoelectric elements in a second electric current direction opposite to the first electric current direction,

FIG. 3a a first current-time diagram for illustrating the electric energization of the thermoelectric elements with an electric alternating current,

FIG. 3b a second current-time diagram for illustrating the electric energization of the thermoelectric elements with an electric alternating current,

FIG. 4 a temperature-time diagram which illustrates the temperature development over time on the top side and bottom side of the heat exchanger with electrically energized thermoelectric elements in accordance with the method according to the invention,

FIG. 5 a special technical configuration of the heat exchanger of FIGS. 1 and 2, in which the thermoelectric device with the thermoelectric elements is formed by a thermoelectric fabric.

### DETAILED DESCRIPTION

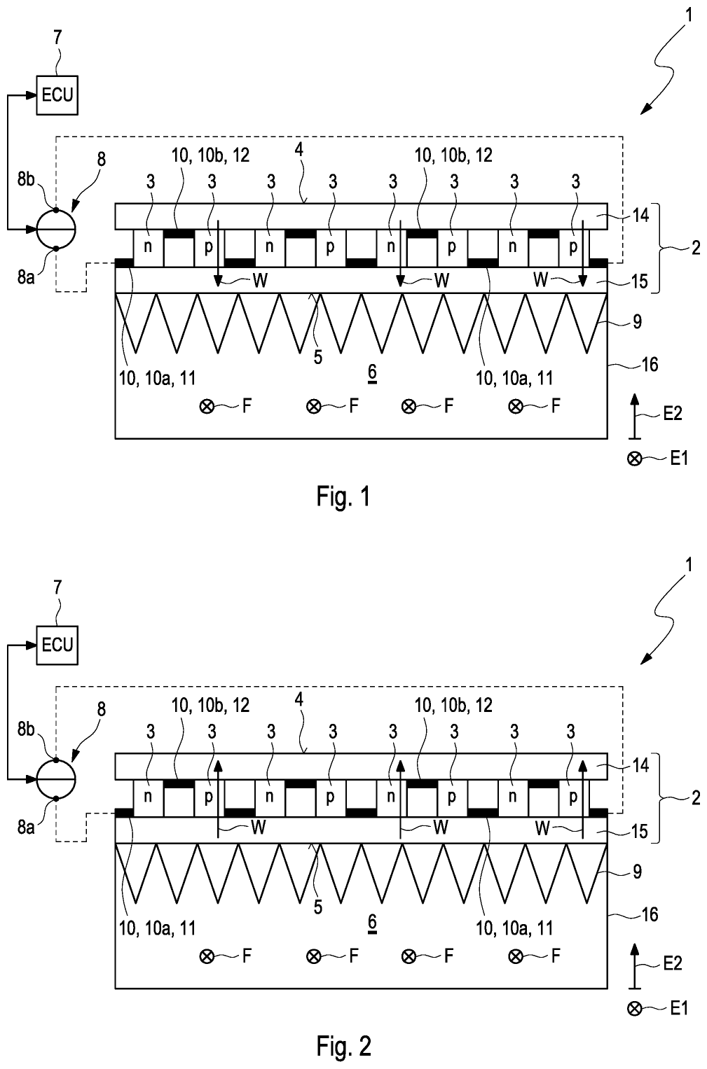

FIG. 1 illustrates an example of a heat exchanger 1 according to the invention for temperature controlling a vehicle seat. The heat exchanger 1 comprises a thermoelectric device 2 which includes multiple electrically energizable thermoelectrically active elements 3. The elements 3, electrically connected in series, can be wired to one another by means of electrically conductive conductor bridges 10 and be alternately formed by a semi-conductor of a p-doped and n-doped material. Possible semi-conductor materials are for example bismuth as well as tellurium or bismuth telluride.

According to FIG. 1, the elements 3 are arranged spaced apart from one another between a top side 4 and a bottom side 5 of the heat exchanger 1. The terms “top side” and “bottom side” relate to a preferred usage position of the heat exchanger 1, in particular when the same is integrated in the said vehicle seed: in this case the top side 4 faces the seating surface of the vehicle seat. When the heat exchanger 1 is integrated in other components this takes place in such a manner that the top side 4 faces the surface to be temperature controlled. The elements 3 can be arranged between a top side substrate 14 and a bottom side substrate 15. The two substrates 14, 15 are preferably designed so as to be electrically insulating and particularly preferably consist of a material with high thermal conductivity.

Furthermore, the heat exchanger 1 comprises a fluid path 6 that is thermally connected to the bottom side 5 and arranged on the bottom side 5 for being flowed through by a fluid F. The fluid path 6 can be designed as fluid channel and for this purpose be delimited for example by a suitable tubular body 16. Apart from this, a control/regulating device 7 is provided which is equipped/configured for carrying out the method. An electric alternating power source 8 with a first and a second connection 8a, 8b serves for generating the electric current I in the thermoelectric device 2. For this purpose, the power source 8 is designed so as to be controllable by the control/regulating device 7 and the two connections 8a, 8b are electrically connected to the thermoelectrically active elements 3.

In the fluid path 6, a heat-transferring structure 9 for the more efficient transfer of heat between the fluid F flowing through the fluid path 6 and the thermoelectrically active elements 3 can be arranged.

In the example of the figures, the fluid paths 6 extend along a first extension direction E1. The first extension direction E1 is a main flow direction of the fluid F through the fluid path 6 or through the fluid channel.

Practically, the top side 4 and the bottom side 5 are situated along a second extension direction E2 of the heat exchanger 1, which extends orthogonally to the first extension direction E1, opposite to one another.

The thermoelectric device 2 includes—as already mentioned—multiple electrical conductor bridges 10 for electrically interconnecting the thermoelectrically active elements 3. These electrical conductor bridges 10 are composed of first conductor bridges 10a facing—with respect to the second extension direction E2—the bottom side 5 and second conductor bridges 10b facing the top side 4. The first conductor bridges 10a can be arranged on the bottom side substrate 15. The second conductor bridges 10b can be arranged on the top side substrate 14. The first conductor bridges 10a form a cold side 11 of the thermoelectric device 2. The second conductor bridges 10b form a warm side 12 of the thermoelectric insulation 2.

In the example of FIG. 1, the electric energization of the thermoelectrically active elements 3 takes place in such a manner that heat (see arrows W) is transported from the top side 4 to the bottom side 5 of the heat exchanger 1. In this way, the top side 4 is cooled through the heat discharge.

Compared with this, FIG. 2 shows a scenario in which the thermoelectrically active elements 3 are electrically energized in such a manner that heat is transported from the bottom side 5 to the top side 4 of the heat exchanger 1. In this way, the top side 4 is heated through the supply of heat.

When carrying out the method according to the invention, the thermoelectric elements 3 of the thermoelectric device 2 are energized with an electric alternating current I(t) so that an average first period tm₁, in which the electric energization of the thermoelectrically active elements 3 takes place in such a manner that heat W is transported form the top side 4 to the bottom side 5, is shorter than an average second period tm2, in which the electric energization of the thermoelectrically active elements 3 takes place in such a manner that heat W is transported from the bottom side 5 to the top side 4.

The average first period tm₁ and the average second period tm2 are preferably fixed so that the heat quantity transported during a cycle T of the electric alternating current I(t) from the bottom side 5 to the top side 4 substantially corresponds to the heat quantity transported from the top side 4 to the bottom side 5 plus the heat quantity (Joule heat) generated by the thermoelectrically active elements 3 through dissipation.

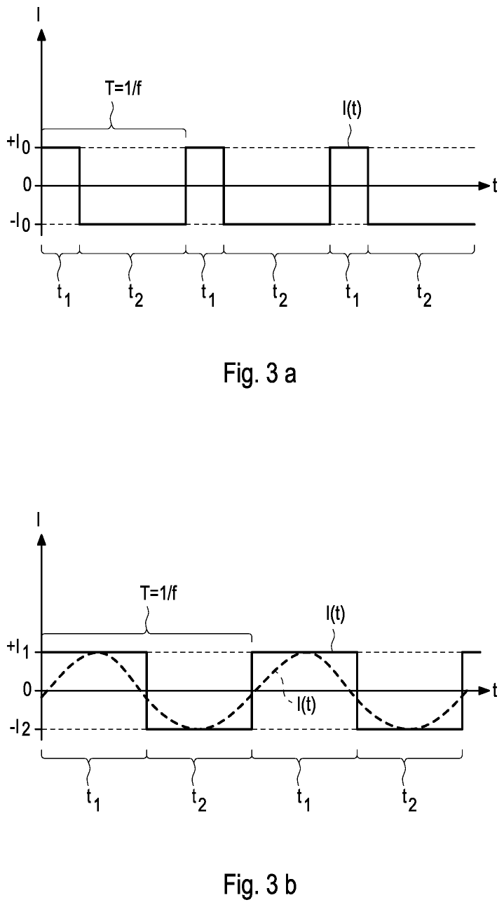

Such a cycling of the electric alternating current I(t) that is substantial for the invention is exemplarily reproduced in the current-time (I-t) diagram of FIG. 3a. It is noticeable that the alternating current I(t) follows a rectangular time profile with alternately positive and negative current values +I₀ or −I₀. Within a respective cycle T the period t2, in which the electric alternating current I(t) assumes the negative current value −I₀ is three times that of the period t1, in which the electric alternating current I(t) assumes the positive value I₀. This constitutes a technically easily realisable possibility of achieving the required different average periods tm₁, tm₂. For the average second period tm₂ a three-fold value of the first average period tm₁ materialises. The electric alternating current I(t) is thus generated in the exemplary scenario with a predetermined cycle ratio of 1:3. Different cycle ratios are also conceivable in variants of the example. The rectangular current course exemplarily shown in FIG. 3a can also be replaced with other suitable current courses—for example ramp-shaped triangular or sinusoidal. The desired heating of the top side 4 with substantially constant temperature T_{U} of the bottom side 5 at the same time is ensured in that a cycle ratio of at least 1:15, preferably between 1:2 and 1:10 is selected. The cycle ratio to be preferably selected can be taken from a predetermined characteristic map stored in the control/regulating device 7. Practically, the alternating current frequency f of the electric alternating current I amounts to at least 1 Hz, preferably at least 10 Hz. Thus, a cycle T of the alternating current I defined by the sum of first- and second-period t1, t2 amounts to maximally 1 s, preferably maximally 1/10 s.

FIG. 3b shows a variant of the example of FIG. 3a. In the example of the FIG. 3b, an average first current Im₁, in which the electric energization of the thermoelectrically active elements 3 takes place in such a manner that heat W is transported from the top side 4 to the bottom side 5 is smaller than an average second current Im2, in which the electric energization of the thermoelectrically active elements 3 takes place in such a manner that heat is transported from the bottom side to the top side. Analogously to the example of FIG. 3a, heat W is thus also transported as a result from the bottom side 4 to the top side 4. It is noticeable that the alternating current I(t) in the example of FIG. 3b has a rectangular profile with alternately positive and negative current values +I₁ or −I₂. In this case 1 Im₁ 1=I₁ and 1 Im₂ 1=I₂ applies. The amount of the positive current value I₁ is lower than the amount of the second current value I₂, i.e. 1 Im₁ 1<1 Im₂ 1.

Instead of a rectangular current profile, a sinusoidal current profile can also be selected for the alternating current I(t) for example, which in FIG. 3b is complementarily shown in dashed representation. The two current values +I₁ and −I₂ correspond to the maximum or minimum value of the sine curve. The average first current Im₁ is thus obtained by averaging the current value I(t) over the first positive half wave of the sine curve. The average second current Im2 is accordingly obtained by averaging the current value I(t) over the second negative half wave of the sine curve.

In contrast with the example of FIG. 3a, the period t1 with positive current value in the example of FIG. 3b is identical to the period t2 with negative current value.

It is expressly emphasised that the exemplary scenarios explained by way of the FIGS. 3a and 3b can also be combined with one another.

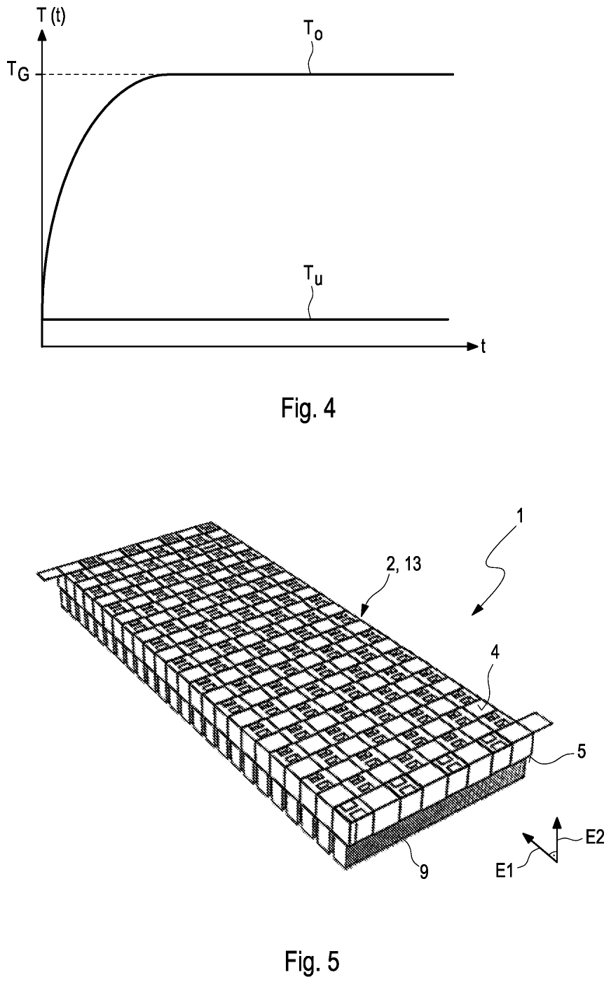

The average first period tm₁ and the average second period tm2 are fixed for carrying out the method both in the example of FIG. 3a so that a temperature T_{O} of the top side 4 converges against a defined temperature limit value T_{G} and a temperature of the bottom side T_{U} remains substantially constant. This scenario is reproduced in the temperature-time (T-t-) diagram of FIG. 4. The same applies to the current values I₁, I₂ in the example of FIG. 3b. The absolute value of the temperature limit value T_{G} can be adapted by changing the current I(t) to the respective requirements.

In a variant which is not shown, the current I₀ or I₁, I₂ can also be a zero value at times which corresponds to an interruption of the electric energization of the thermoelectrically active elements 3.

FIG. 5 shows a preferred configuration variant of the heat exchanger. In the example of FIG. 5, the thermoelectric insulation 2 is formed as thermoelectric fabric 13. The terms “fabric” and “threads” refer primarily to the arrangement of the multiple flexible longitudinal components of which the “fabric” is composed. These are arranged similarly to the “threads” in a classic textile fabric, which is why for illustration the terms weft, threads and warp threads as well as fabric are used here.

As is evident from FIG. 5, the term “thread” also includes flexible band-like structures or longitudinal block-like structures here. The fabric 13 can include a plurality of first threads which are alternately formed by p-doped and n-doped thread portions and electrically conductive first and second thread portions arranged in between. Here, the first thread portions of the fabric 13 form the first conductor bridges 10a and the second thread portions of the fabric 13 form the second conductor bridges 10b of the installation 2.

Furthermore, the fabric 13 comprises a plurality of second threads which are preferentially formed so as to be electrically insulating. In the case of the fabric 13, the first threads form the weft threads and the second threads the warp threads or vice versa. The heat exchanger 1 with the thermoelectric fabric 13 shown in FIG. 5 is particularly suitable for integration in a vehicle seat. The top side 4 of the fabric 13 is then practically arranged in the region of a seating surface of the vehicle seat assigned to the top side 4. When carrying out the method according to the invention, heat is transported “nett” from the bottom side 5 to the top side 4 and the seating surface thus heated.

1. A method for operating a heat exchanger comprising a top side, a bottom side, and a thermoelectric device including thermoelectrically active elements which are designed electrically energizable for generating a heat flow between the top side and the bottom side, the method comprising:
electrically energizing the thermoelectric device with an electric alternating current;
wherein an average first period, in which the electric energization of the thermoelectrically active elements takes place in such a manner that heat is transported from the top side to the bottom side, is shorter than an average second period, in which the electric energization of the thermoelectrically active elements takes place in such a manner that heat is transported from the bottom side to the top side; or/and that and
wherein an average first current, in which the electric energization of the thermoelectrically active elements takes place in such a manner that heat is transported from the top side to the bottom side, is lower than an average second current, in which the electric energization of the thermoelectrically active elements takes place in such a manner that heat is transported from the bottom side to the top side.

2. The method according to claim 1, wherein
the electric energization includes a zero value for the electric alternating current.

3. The method according to claim 1, wherein
the average first period and the average second period or the average first current and the average second current are fixed so that heat quantity transported during a cycle of the electric alternating current from the bottom side to the top side corresponds to heat quantity transported from the top side to the bottom side plus heat quantity generated by the thermoelectrically active elements through dissipation and transported to the bottom side.

4. The method according to claim 1, wherein
the average first period and the average second period or the average first current and the average second current are fixed so that a temperature of the top side with respect to time converges against a defined temperature limit value; and/or the average first period and the average second period or the average first current and the average second current are fixed so that a temperature of the bottom side remains substantially constant.

5. The method according to claim 1, wherein
the electric alternating current is generated with a predetermined cycle ratio so that the average second period amounts to at least 1.5 times the average first period.

6. The method according to claim 5, wherein
the cycle ratio is taken from a predetermined characteristic map.

7. The method according to claim 1, wherein
an alternating current frequency[[ (f)]] of the electric alternating current[[ (I)]] amounts to at least 1 Hz.

8. A heat exchanger for controlling temperature of a vehicle seat, comprising:
a thermoelectric device including multiple electrically energizable thermoelectrically active elements which, spaced apart from one another, are arranged on a top side and a bottom side of the heat exchanger;
a fluid path provided on the bottom side and thermally connected to the same for being flowed through by a fluid; and
a control/regulating device configured to carry out the method according to claim 1.

9. The heat exchanger according to claim 8, wherein
the heat exchanger comprises an electric power source for generating an electric current in the thermoelectrically active elements of the thermoelectric device or is designed so as to be electrically connectable to such an electric power source.

10. The heat exchanger according to claim 8, wherein
in the fluid path a heat transferring structure for transferring heat between the fluid flowing through the fluid path and the thermoelectrically active elements is arranged.

11. The heat exchanger according to claim 8, wherein
the thermoelectric device is configured so that upon electric energization of the thermoelectrically active elements in a first electric current direction heat is transported from the top side to the bottom side and upon electric energization of the thermoelectrically active elements in a second electrical current direction opposite the first electric current direction heat is transported from the bottom side to the top side.

12. The heat exchanger according to claim 8, wherein
the thermoelectric device includes multiple electric conductor bridges for electrically interconnecting the thermoelectrically active elements; and
wherein a respective conductor bridge is thermally connected either to a warm side or to a cold side of installation.

13. The heat exchanger according to claim 12, wherein
the electric conductor bridges comprise first conductor bridges facing the bottom side, which form the cold side or the warm side of the thermoelectric device and second conductor bridges facing the top side, which form the warm side or the cold side of the thermoelectric device.

14. The heat exchanger according to claim 13, wherein
during an operation of the heat exchanger, the first conductor bridges form the cold side.

15. The heat exchanger according to claim 14, wherein
the thermoelectric device includes a thermoelectric fabric or is formed as thermoelectric fabric, wherein the thermoelectric fabric includes:
a plurality of first threads which are alternately formed by p-doped and n-doped thread portions and electrically conductive first and second thread portions arranged in between, wherein the first thread portions of the fabric form the first conductor bridges and the second thread portions form the second conductor bridges of the heat exchanger; and
a plurality of second threads which are preferentially formed so as to be electrically insulating;
wherein the first threads form weft threads and the second threads form warp threads of the fabric, or vice versa.

16. A vehicle seat, comprising
the heat exchanger according to claim 8;
wherein the top side of the heat exchanger is thermally connected to a seating surface of the vehicle seat.

17. The method according to claim 1, wherein the electric alternating current is generated with a predetermined cycle ratio so that the average second period amounts to approximately 2 to 10 times the average first period.

18. The method according to claim 1, wherein an alternating current frequency of the electric alternating current amounts to at least 10 Hz.

19. The heat exchanger according to claim 14, wherein during the operation of the heat exchanger, the second conductor bridges form the warm side.

20. The heat exchanger according to claim 8, wherein the thermoelectric device includes a thermoelectric fabric.
